(19) United States
(12) Patent Application Publication
(10) Pub. No.: US 2011/0226617 A1
(43) Pub. Date: Sep. 22, 2011

(54) DIELECTRIC DEPOSITION USING A REMOTE PLASMA SOURCE

(75) Inventors: Ralf Hofmann, Soquel, CA (US); Majeed A. Foad, Sunnyvale, CA (US)

(73) Assignee: APPLIED MATERIALS, INC., Santa Clara, CA (US)

(21) Appl. No.: 13/069,205

(22) Filed: Mar. 22, 2011

Related U.S. Application Data
(60) Provisional application No. 61/316,306, filed on Mar. 22, 2010.

(51) Int. Cl. C23C 14/34; C23C 14/35; C23C 14/06; C23C 14/46

(52) U.S. Cl. 204/298.04; 204/298.17; 204/298.18; 204/298.13

(57) ABSTRACT

A sputter deposition system comprises a vacuum chamber including a vacuum pump for maintaining a vacuum in the vacuum chamber, a gas inlet for supplying process gases to the vacuum chamber, a sputter target and a substrate holder within the vacuum chamber, and a plasma source attached to the vacuum chamber and positioned remotely from the sputter target, the plasma source being configured to form a high density plasma beam extending into the vacuum chamber. The plasma source may include a rectangular cross-section source chamber, an electromagnet, and a radio frequency coil, wherein the rectangular cross-section source chamber and the radio frequency coil are configured to give the high density plasma beam an elongated ovate cross-section. Furthermore, the surface of the sputter target may be configured in a non-planar form to provide uniform plasma energy deposition into the target and/or uniform sputter deposition at the surface of a substrate on the substrate holder. The sputter deposition system may include a plasma spreading system for reshaping the high density plasma beam for complete and uniform coverage of the sputter target.

### CROSS-REFERENCE TO RELATED APPLICATIONS

This application claims the benefit of U.S. Provisional Application Ser. No. 61/316,306 filed Mar. 22, 2010, incorporated by reference in its entirety herein.

### FIELD OF THE INVENTION

The present invention relates generally to sputter deposition process tools, and more particularly to high productivity sputter deposition systems for dielectric materials configured with a plasma source remote from the sputter target.

### BACKGROUND OF THE INVENTION

Deposition rates in conventional radio frequency (RF) sputtering of dielectric materials are limited by the power density that can be applied to the target before the material cracks due to internal thermal stresses. Dielectric materials are usually poor heat conductors. The magnetron in conventional sputtering sources confines the Ar plasma in a racetrack pattern. This results in a non-uniform power density across the target, causing uneven heating of the target, build-up of internal stresses and even cracking in the target.

In particular, dielectric targets used for sputter depositing lithium phosphorus oxynitride (LiPON) electrolyte material in the fabrication of thin film batteries are susceptible to cracking. Currently, deposition rates for LiPON films are kept low to avoid cracking the target material. There is a need for improved methods and apparatus for deposition of LiPON films.

### SUMMARY OF THE INVENTION

Embodiments of the present invention provide sputter deposition tools and methods that provide manufacturing advantages for UPON deposition for thin film batteries using Li₃PO₄ (lithium orthophosphate) sputtering targets. By using a remote plasma source, such as offered by Plasma Quest Ltd, U.K. and described in U.S. Pat. Nos. 6,463,873 and 7,578,908 and at www.plasmaquest.com.uk (last visited on Mar. 19, 2010), a more uniform argon ion distribution across the Li₃PO₄ target can be achieved. This results in more even heating of the Li₃PO₄ target, resulting in reduced thermal stress. Thus the power density can be increased, resulting in higher LiPON deposition rates.

Furthermore, improvements to the plasma source and improvements to the deposition chamber are described herein which permit the use of remote plasma sources for sputtering of large size dielectric targets typically used in semiconductor integrated circuit manufacturing—13 inch targets for 200 mm substrates and 17 inch targets for 300 mm substrates. For example, instead of a cylindrical plasma source, a plasma source with a large aspect ratio may be used to generate an elongated plasma suitable for covering large target sizes. The target configuration may be improved to provide more uniform target erosion, for example by shaping the target to compensate for non-uniform erosion. The plasma may be spread in the deposition chamber to cover a large target using electromagnets and/or magnet (permanent magnet or magnetic material).

According to aspects of this invention, a sputter deposition system, comprises: a vacuum chamber including a vacuum pump for maintaining a vacuum in the vacuum chamber; a gas inlet for supplying process gases to the vacuum chamber; a sputter target within the vacuum chamber; a substrate holder within the vacuum chamber; and a plasma source attached to the vacuum chamber and positioned remotely from the sputter target, the plasma source being configured to form a high density plasma beam extending into the vacuum chamber. The plasma source may comprise: a rectangular cross-section source chamber; an electromagnet; and a radio frequency coil; wherein the rectangular cross-section source chamber and the radio frequency coil are configured to give the high density plasma beam an elongated ovate cross-section. Furthermore, the surface of the sputter target may be configured in a non-planar form to provide uniform plasma energy deposition into the target and/or uniform sputter deposition at the surface of a substrate on the substrate holder. According to further aspects of the invention, the sputter deposition system may include a plasma spreading system for reshaping the high density plasma beam for complete and uniform coverage of the sputter target.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a perspective view of a prior art sputter deposition system with a remote plasma source;

FIG. 2 is a schematic cross-sectional representation of the source and process chambers of a first prior art sputter deposition system;

FIG. 3 is the schematic cross-sectional representation of FIG. 2 showing magnetic flux lines due to the chamber solenoids.

FIG. 4 is a schematic cross-sectional representation of the source and process chambers of a second prior art sputter deposition system with steering magnets for steering the plasma beam;

FIG. 5 is a schematic cross-sectional representation of the source and process chambers of a third prior art sputter deposition system with steering magnets for steering the plasma beam;

FIG. 6 is a schematic cross-sectional representation of the source and process chambers of a fourth prior art sputter deposition system;

FIG. 7 is a detail of an alternative prior art target assembly for the sputter deposition system of FIG. 6;

FIG. 8 is a schematic representation of a first example of a remote plasma source, according to some embodiments of the present invention;

FIG. 9 is a schematic representation of a second example of a remote plasma source, according to some embodiments of the present invention;

FIG. 10 is a cross-sectional representation of an example of a target geometry which results in non-uniform film thickness;

FIG. 11 is a cross-sectional representation of an example of a target geometry for improving film thickness uniformity, according to some embodiments of the present invention;

FIG. 12 is a schematic representation of a first example of a system configuration for shaping the plasma, according to some embodiments of the present invention; and

FIG. 13 is a schematic representation of a second example of a system configuration for shaping the plasma, according to some embodiments of the present invention.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Li₃PO₄ (lithium orthophosphate) sputtering targets are used for electrolyte deposition for thin-film batteries. More specifically, lithium phosphorus oxynitride (LiPON) electrolyte material is deposited by sputter deposition of lithium orthophosphate in a nitrogen environment. To reduce non-uniform heating of the target, a remote plasma source is utilized—avoiding the non-uniform power density of conventional magnetron sputtering sources which confine the argon plasma in a racetrack pattern at the target. The remote plasma source provides a more uniform argon ion distribution across the Li₃PO₄ target. This results in more even heating of the Li₃PO₄ target, resulting in reduced thermal stress. Thus the power density can be increased, resulting in higher LiPON deposition rates. An example of the remote plasma source is the plasma source offered by Plasma Quest Ltd, U.K. and described in U.S. Pat. Nos. 6,463,873 and 7,578,908 and at www.plasmaquest.com.uk (last visited on Mar. 19, 2010).

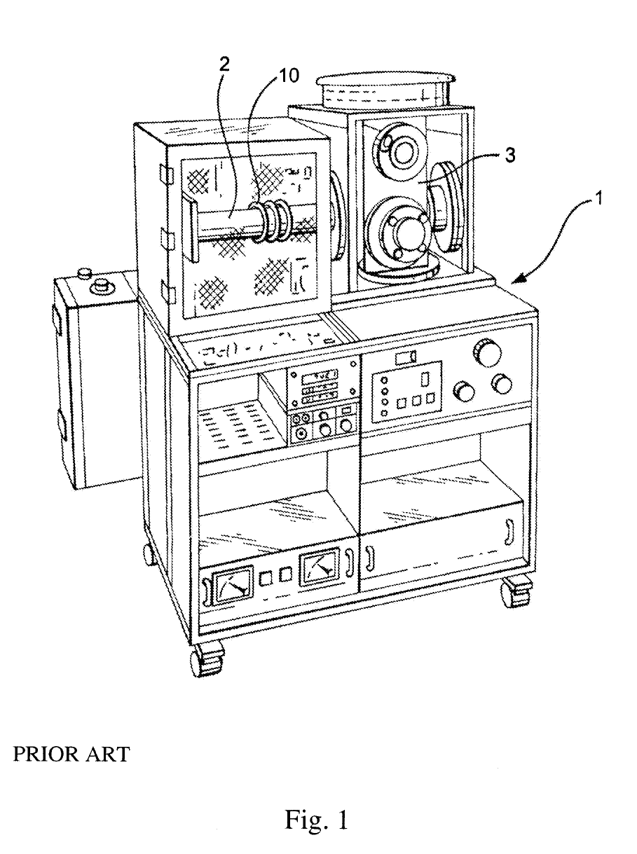

A sputter deposition system with a remote plasma source is described in U.S. Pat. No. 6,463,873 assigned to Plasma Quest Ltd., U.K. The details of this system are provided herein with reference to FIGS. 1-5.

FIG. 1 shows the external appearance of a Plasma Quest prior art system having a process chamber 3 and a source chamber 2 with an associated coil 10.

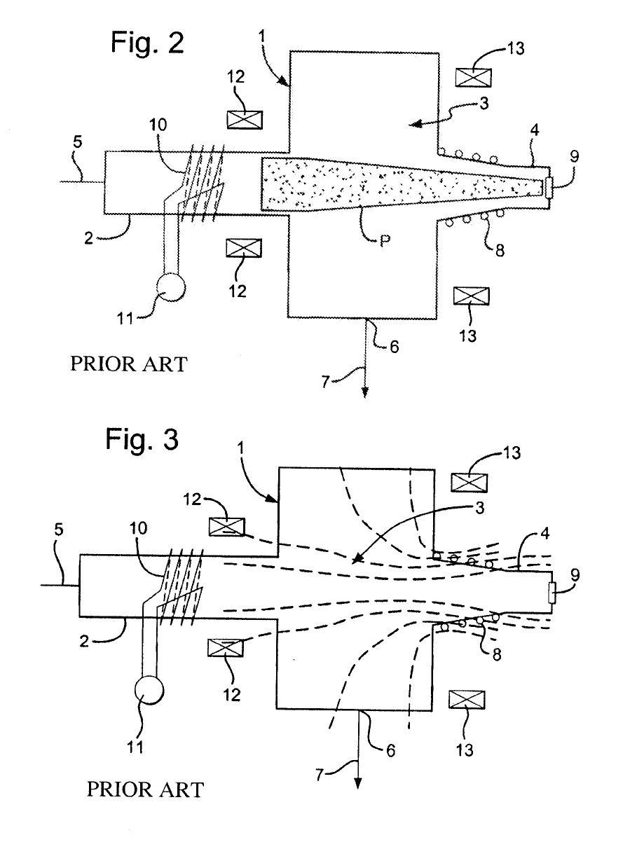

FIG. 2 shows a schematic representation of a first Plasma Quest prior art system. There is shown therein a substantially cylindrical vacuum chamber 1 having a source chamber 2 of a first cross section, a process chamber 3 of larger cross section and a termination end 4 of tapering cross section. The source chamber has an inlet 5 in to which ionizable process gas can be introduced. The process chamber 3 has an outlet 6 attached to vacuum pumps at 7 for evacuating the vacuum chamber 1 and, in use of the apparatus, causing a flow of process gas therethrough. The termination end 4 is water cooled by a helically arranged water pipe 8; the end of the termination end 4 contains a glass view port 9 for observing the plasma “P” generated in the chamber. A helically wound coil annular antenna 10 having four turns and being in the form of a brass strip whose ends are electrically insulated from each other with one end connected to an RF power supply 11 and the other end connected to earth. The four turns were each spaced apart from adjacent turns by about one or two centimeters. The overall length of the antenna was of the order of six to eight centimeters. The RF supply was at a frequency of 13.56 MHz. About the antenna and co-axial therewith is a source magnet 12 in the form of an annular solenoid having an internal diameter slightly greater than the external diameter of the antenna and electrically isolated therefrom. Activation of the solenoid magnet 12 is by connection to a power source (not shown). About the termination end 4 of the chamber 1 is a chamber magnet 13 in the form of another annular solenoid having a larger diameter than the source magnet 12.

The exemplified apparatus of FIG. 2 has a source chamber 2 made of quartz and an internal diameter of one-hundred-and-fifty millimeters, a wider process chamber 3 and a termination end 4 of initial diameter the same as that of the source chamber 2 but tapering in a direction away from process chamber 3. In use of the apparatus with the vacuum pumps at 7 turned on, the source and chamber solenoids 12, 13 respectively are both turned on with the windings of both solenoids generating magnetic fields parallel, to the axis of the process chamber in the same direction and the chamber magnet 13 generating the larger individual magnetic field effect (5×10⁻² Tesla) than that of the source magnet (5×10⁻³ Tesla) but with the fluxes of the respective magnetic fields being linked to produce a non-axial magnetic field overall relative to the main (longitudinal) axis of the helically wound coil antenna 10. Typical flux lines of such a non-axial magnetic field are shown in FIG. 3 showing the same type of apparatus to that of FIG. 2. It should be noted, however, that the use of a uniform magnet field is not essential as generally there will be some non-uniformity in respect of the magnetic field. The magnetic field so formed means that in use there is a magnetic gradient 3 increasing in a direction away from the antenna 10 and the generated RF electric field must interact with lines of magnet flux in the vacuum chamber. In addition, cooling water was passed through the helically arrayed pipe 8 and argon (ionizable) gas was present in the evacuated vacuum chamber 1 the chamber pressure should preferably range between 7×10⁻⁵ mbar and 2×10⁻² mbar.

The operation of the apparatus shown in FIG. 2 showed that a high density plasma beam P was formed at low pressures. In particular, the argon ion efficiency was calculated to be in excess of thirty percent at 5 kW power and 8×10⁻⁴ mbar pressure.

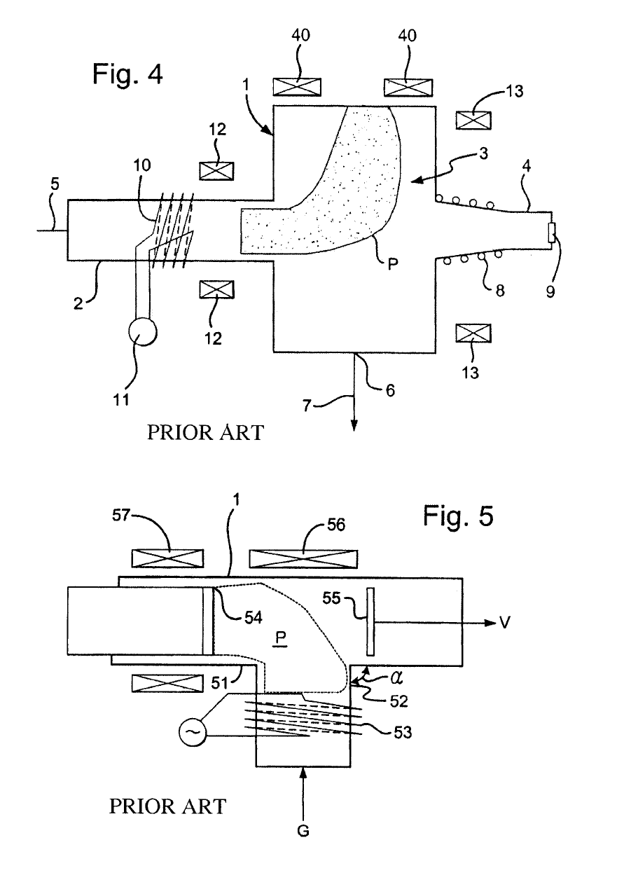

FIG. 4 shows the use of a steering magnet 40 as an addition to the apparatus shown in FIG. 2. This steering magnet is in the form of an annular solenoid positioned on one side of the process chamber 3 (the top as shown). In use, the polarity of the solenoid magnet determines whether the plasma beam P is deflected or steered towards the steering magnet 40 (as shown) or alternatively away from the magnet. The ability to steer the plasma beam may be of considerable benefit in certain coating methods in which the control of the direction of the plasma in relation to the substrate is important, for example a substrate positioned in the upper or lower part of the process chamber 3. In this respect, FIG. 5 shows the use of a source chamber having a central longitudinal axis parallel with, but not co-linear with the plane of the target. The target being positioned such that plasma entering the process chamber from the source chamber needs to be substantially deflected towards the target.

The apparatus of FIG. 5 includes a cylindrical vacuum chamber 1 having a process chamber 51 and a source chamber 52 in which a RF helically wound coil antenna 53 is deployed. Also present in the chamber 1 is a target 54 having a surface of material to the sputtered and a substrate 55 in to which the target material is to be deposited. Electromagnetic means 56 at the top (as shown) of the process chamber 51 opposite the source chamber 52, or to the right of the antenna and further electromagnetic means 57 positioned about the process chamber 51 provide, in use of the apparatus, magnetic means to generate a magnetic field which, by interaction with the electric field profile of the RF antenna 53 in use of the apparatus, produces a high density plasma wave.

In use of the apparatus of FIG. 5, introduction of gas, for example again, in to the chamber in the direction of the arrow G will be chamber 1 evacuated by means of vacuum pumps (not shown) acting in the direction of the arrow V again allows a very high intensity plasma to be generated by means of the high density plasma wave propagated from the helically wound coil antenna 53 and to be present by virtue of the electromagnetic means 56, 57 in the general area with dotted lines indicated by the reference letter P between the target 54 and a substrate 55.

The ability to produce a high intensity plasma P in FIG. 5 between the target 54 and the substrate 55 from an antenna 63 present in the source chamber and therefore remote from the coating area of the chamber clearly affords the possibility of avoiding or at least minimizing RF leakage from the antenna in that substantially no coating of the internal wall of the chamber should occur in the source chamber in the vicinity of the antenna 53.

It is possible for the source chamber 52 to have a different orientation to that shown in FIG. 5 by making the angle more than the ninety degrees shown in FIG. 5, for example one hundred and thirty-five degrees. This would afford the greater possibility of avoiding RF leakage from the antenna 53 in that even less coating should be effected on the wall of the source chamber 52.

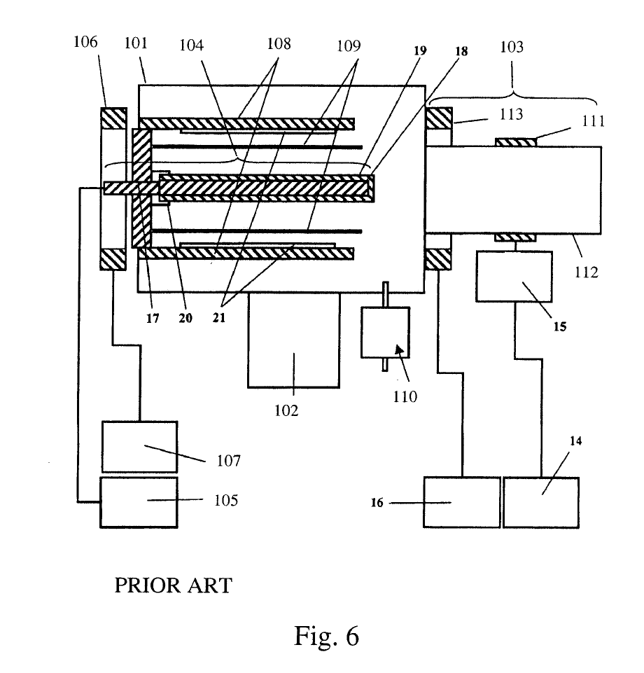

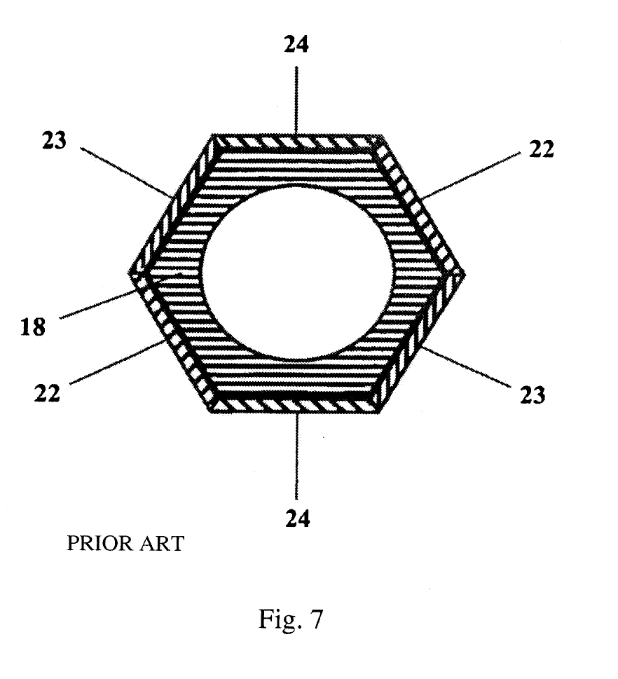

Further details of a sputter deposition system with a remote plasma source is described in U.S. Pat. No. 7,578,908 assigned to Plasma Quest Ltd., U.K. The further details of this system are provided herein with reference to FIGS. 6-7.

FIG. 6 shows a fourth Plasma Quest prior art system. In FIG. 6, a vacuum chamber 101 and controllable means of vacuum pumping the chamber by a pumping system 102 are fitted with a remote plasma generation system 103, a cylindrical target assembly 104, a DC power supply 105, a ring electromagnet 106 and associated DC power supply 107 capable of producing an axial magnetic field of 100 to 500 Gauss, substrate carriers 108, shutter assemblies 109 and a controllable process gas feed system 110. The remote plasma generation system 103 comprises a coil antenna 111 external to a quartz tube 112 that is mounted on the vacuum chamber 101, a ring electromagnet 113 surrounding the quartz tube 112 at or near its connection to the vacuum chamber 101, a 13.56 MHz AC RF generator 14 and impedance matching network 15 connected to the coil antenna 111, and a DC power supply 16 electrically connected to the ring electromagnet 113 and in combination capable of producing an axial magnetic field of 100 to 500 Gauss. The cylindrical target assembly 104 comprises a vacuum chamber feedthrough 17 that feeds water and electric services to a mounting assembly 18, this being thereby water cooled and capable of having a voltage applied to it from sources external to the vacuum chamber. Additionally a target material 19 is fitted around the mounting assembly 18, ensuring good electrical and thermal contact by means well known in the art. Additionally in order to prevent sputtering of the feedthrough 17 and mounting assembly 18 a shield 20 that is electrically grounded is provided around these items where they mount to the chamber. The substrate carriers 108 essentially provide a means to position and hold the substrates 21 that are to be coated within the vacuum chamber. The carriers may be water cooled or include heaters to control the substrates temperature, be capable of having a voltage applied to them to assist control of deposited film properties, include means of rotating and/or tilting the substrates to improve uniformity, and themselves be capable of being moved and/or rotated within the vacuum chamber. The shutter assembly 109 is provided such that in the “closed” position target sputtering can take place without coating the substrates. The process gas feed system 110 comprises one or more gas inlets for one or more process gases or process gas mixtures, each gas flow being controllable for example using commercial mass flow controllers, and optionally including gas mixing manifolds and/or gas distribution systems within the vacuum chamber. A single gas inlet may be provided to the vacuum chamber, the process gas or gases then being distributed to all parts of the vacuum by normal low pressure diffusion processes or directed pipework.

In the Plasma Quest prior art system of FIG. 6, the target assembly is constructed so as to provide a stainless steel target material surface of 12 mm diameter and approximately 275 mm exposed length, and placed within the plasma cylinder in the vacuum chamber. The substrates 21 to be coated, which in this example are made of glass, are loaded into the substrate carriers 108 at a distance of 110 mm from the target. The shutter assemblies 109 are set to the closed position. The vacuum chamber 1 is then pumped by the pumping system 102 to a vacuum pressure suitable for the process, for example less than 1×10⁻⁵ torr. The process gas feed system 110 is then used to flow at least one process gas, for example argon, into the vacuum chamber. The flow rate and optionally the rate of vacuum pumping are adjusted to provide a suitable operating pressure for the sputter process, for example 3×10⁻³ torr. The electromagnets 106 and 113 in conjunction with their respective power supplies 107 and 16 are then used to produce a magnetic field of strength approximately 100 to 300 Gauss across the vacuum chamber. The precise shape and strength of this magnetic field is to an extent determined by the precise geometry and requirements of the remainder of the system. In this example ring electromagnet 113 is powered to produce a magnetic field strength of 200 Gauss at its centre; ring electromagnet 106 is powered to produce a magnetic field strength of 200 Gauss to 250 Gauss at its centre. The magnetic “polarity” of each is identical (i.e. they attract), resulting in an approximately cylindrical magnetic flux running across the chamber. The remote plasma is generated by applying RF power, for example 2 kW, from the generator 14 via the matching network 15 to the coil antenna 111. In combination with the magnetic field produced as described above, this results in a high density plasma being produced across the chamber and surrounding the target assembly 104. In this example, the plasma conditions are set to be an argon gas flow of 18.5 sccm, a vacuum system pressure of 4×10⁻³ torr, 0.75 kW RF power applied to the coil antenna and the coil electromagnet 113 axial magnetic field at approximately 200 Gauss and the coil electromagnet 106 axial magnetic field at approximately 250 Gauss. This produces an intense argon plasma of characteristic light blue coloration denoting the presence of a plasma density of approximately 1×10¹³ cm⁻³. The remote plasma generation system in this example produces a cylindrical plasma of approximately 80 mm diameter which can be guided into the vacuum chamber and constrained to the same approximately cylindrical form and diameter by the ring electromagnets 106 and 113. The plasma originating from the remote plasma generation source can be guided and shaped using the ring electromagnets 6 and 13 to completely cover the whole target material surface, with no loss or non-uniformity of plasma density, i.e. the presence of the target material does not block or detrimentally affect the plasma.

A further advantage of the Plasma Quest prior art system of FIG. 6 is that the target assembly does not substantially heat up, even in the absence of water cooling, despite being placed within the high density plasma. The plasma produced by the remote plasma system and constrained by the magnetic field is not disrupted by the presence of the target. This is because although the plasma is cylindrical overall, the plasma generation region is tubular and of a diameter similar to that of the quartz tube 112 and therefore not intercepted by the smaller diameter target. As the plasma generation region is also the region into which most of the remote plasma generation system energy is directed, only items intercepting this region are substantially heated. The DC power supply 105 is then used to apply a negative polarity voltage to the cylindrical target assembly 104. This results in ions from the plasma in the vicinity of the target being attracted to the target and, if the voltage is above the sputter threshold value for the target material (typically in excess of 65 volts), sputtering of the target material will occur. As the sputter rate for this example system is approximately proportional to the voltage above this threshold value, voltages of 600 volts or more will usually be applied; for very high rate applications higher voltages may be used, for example 1200 volts. In this example, a negative polarity DC voltage of 500V is applied to the target assembly (and thereby the target material) for a period of one minute using the DC power supply 105. The plasma density required to produce this current is in the order of 1.76×10¹³ cm⁻³. After an optional time delay to allow the target surface to clean and stabilize, for example 5 minutes, the shutter assemblies 109 are set to the open position to expose the surface of substrates 21 facing the cylindrical target assembly to the sputtered material, thereby coating the substrate surfaces with a film of the target material 19. After a time determined by the required film thickness and the deposition rate at the substrate surface, the shutter assemblies 109 are set to the closed position and deposition onto the substrates ceases. The various power supplies and gas flows can then be turned off as required and the vacuum system vented to atmospheric pressure using a suitable gas, for example nitrogen or air, to permit recovery and subsequent use of the coated substrates.

Using a prior art Plasma Quest system such as shown in FIG. 6, and using stainless steel as the target material, substrates may be coated with a film of stainless steel of thickness 70 nm, corresponding to a deposition rate of 1.17 nm·s⁻¹, with the deposition area defining a cylinder surrounding the target assembly with deposition being uniform for approximately 150 mm longitudinal length. Thus the area onto which substrates can be placed for uniform coating is approximately 1×10⁵ mm².

In other prior art systems, the same plasma source as described above for FIG. 6 operating at similar conditions and directed onto a planar 100 mm diameter target through a magnetically induced 90 degree bend and voltage biased to 500V negative polarity would produce a deposition rate of less than 0.3 nm·s⁻¹ onto a uniform deposition area of approximately 8×10³ mm².

In the prior art Plasma Quest system of FIG. 6, an appropriately sized substantially cylindrical target is placed within a cylindrical plasma originating from a remote plasma source, which gives a dramatic improvement in deposition rate and deposition area. That the cylindrical plasma is not extinguished by placing the target within it is due to the plasma generation tube lying outside of and around the target. This configuration maximizes the efficiency with which the plasma is used, as the target surface is in proximity to the whole of the plasma generation tube that propagates across the vacuum chamber.

In a first prior art alternative embodiment of the Plasma Quest system of FIG. 6, the target material 19 and mounting assembly 18 are of non-circular external cross section, for example hexagonal. This might be preferred over the original embodiment's substantially circular cross section in order for example to make construction easier or provide an improved uniformity of deposition to the substrates.

In a second prior art alternative embodiment of the Plasma Quest system of FIG. 6, shown in FIG. 7, the single target material 19 is replaced by two or more differing target materials, for example the three target materials 22 and 23 and 24, on a hexagonal cross section mounting assembly 18, so as to direct different material coatings to different regions of the vacuum chamber.

The target assembly 4 of FIG. 6 can optionally include means to rotate it about its longitudinal axis. This allows for example the redirection of the materials to different substrate positions at choice and therefore provides a basis for sequential deposition of different thin film materials onto the substrates. Alternatively, the rotation can be continuous and sufficiently fast, for example 100 rpm, that the substrates effectively receive a thin film coating that is a mixture of the target materials. Both these capabilities have wide application in the thin film coatings industry.

In a third prior art alternative embodiment of the Plasma Quest system of FIG. 6, the target shield 20 is extended to cover the whole length of the target material and mounting assembly and includes apertures that thereby allow the plasma to interact with and sputter the target at only those places, thereby limiting and defining the target regions to be sputtered and the region of the vacuum chamber into which sputtering occurs. This alternative embodiment is especially useful when combined with a target comprising several target materials and means of rotation as previously described as it is able to reduce cross-contamination of the materials at the substrates.

Further alternative prior art embodiments of the Plasma Quest system were envisaged. For example, the remote plasma generation source needs only to provide a tubular generation region at its exit to the vacuum chamber and could therefore be provided for example by a “helicon” antenna source. Alternative radio frequencies, for example 40 MHz, could be used to power the remote plasma source antenna. More than two electromagnets or permanent magnets could be used to guide and confine the plasma; for example an additional electromagnet placed between those shown in FIG. 6 could be used to improve the magnetic confinement and thereby allow a longer target length to be used, with commensurate increase in the deposition area in which substrates could be placed.

It has been recognized that the prior art Plasma Quest system of FIG. 6 can also be used in a reactive sputter process, that is a process in which a reactive gas or vapor is introduced via the gas feed system 110 to react with the sputtered target material or materials and thereby deposit a compound thin film on the substrate. For example, oxygen gas can be introduced into the sputter processes described above with reference to FIG. 6 and alternative embodiments in order to deposit oxide thin films, for example to deposit alumina by sputtering of an aluminum target in the presence of oxygen gas or silica by sputtering of a silicon target in the presence of oxygen gas.

Plasma Quest Ltd., U.K. discloses the use/potential use of the Plasma Quest prior art systems to sputter deposit the following materials: metals—Ag, Al, Au, Bi, Co, Cr, Cu, Fe, Hf, In, Mg, Mn, Mo, Nb, Ni, Pb, Pt, Sn, Ta, Ti, W, Y, Zn and Zr; dielectrics—AlN, Al₂O₃, PbO, SiO₂, Ta₂O₅, NbO₅, TiO₂, TiₓO₂ₓ₋₁, TiN, HfO₂, CuO, In₂O₃, MgO and oxy-nitrides and sub-oxides; transparent conducting oxides—Sn:InO (ITO), In:ZnO (IZO), Al:ZnO (AZO) and ZnO; and magnetic materials—Co, CoFe, Fe and NiFe. See www.plasmaquest.com.uk (last visited on Mar. 19, 2010). However, sputter deposition of LiPON and/or the use of Li₃PO₄ target materials is not disclosed.

Plasma Quest Ltd., U.K. also discloses the use/potential use of the Plasma Quest prior art systems in the following application areas: flexible electronics, transparent conducting oxides, magnetic media, high mobility TFTs, photonics and precision optics, optical filters, waveguide materials, photoluminescence devices, electroluminescence devices, barrier layers, protective and wear resistant coatings and alternatives to wet coatings. See www.plasmaquest.com.uk (last visited on Mar. 19, 2010). However, the application area of thin film batteries is not disclosed.

The present invention includes improvements to the systems described above to enable efficient use of remote plasma sources for sputter deposition on large substrates, such as 200 mm and 300 mm substrates.

Improvements to Remote Plasma Source

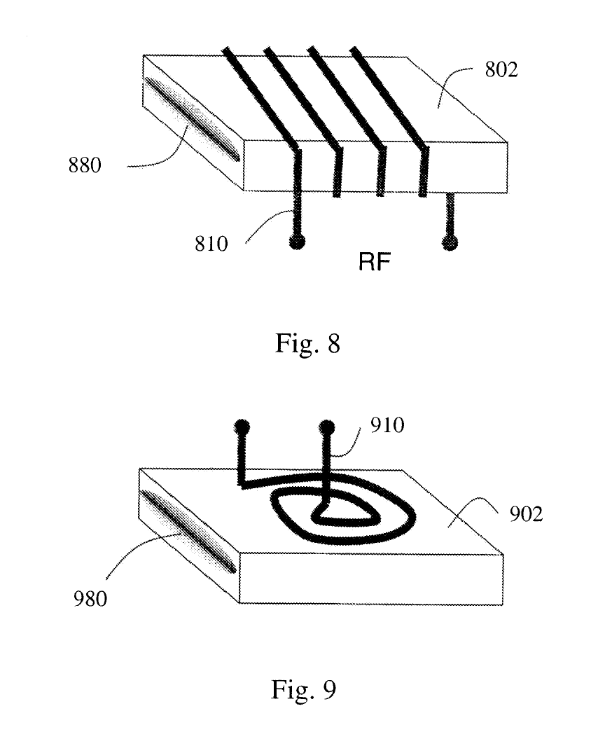

A cylindrical remote plasma source as employed in the prior art can only generate a relatively restricted plasma region. This limits the size of the target that can be sputtered to a few inches in diameter, or a rectangular target of a few inches in width and less than 40 inches in length. By changing the cross section of the plasma generating region to an elongated shape the source should be able to cover target sizes more typical for IC processing (˜13″ for 200 mm and ˜17″ for 300 mm). See FIGS. 8 and 9, which show examples of remote plasma chamber configurations for elongating the plasma cross-section.

FIG. 8 shows a schematic representation of a remote plasma source with a rectangular cross-section source chamber 802 and a first RF coil 810. The plasma 880 is seen to have an elongated ovate cross-section.

FIG. 9 shows a schematic representation of a remote plasma source with a rectangular cross-section source chamber 902 and a second RF coil 910. The plasma 980 is seen to have an elongated ovate cross-section. Note that RF coils 810 and 910 are equivalent to the RF antenna described by Plasma Quest which are used in conjunction with an electromagnet to form a high density plasma beam.

Some examples of the expected dimensions of the rectangular cross-section source chambers of FIGS. 8 & 9 are 200-250 mm in width for a 200 mm spread beam and 300-350 mm for a 300 mm spread beam. The height and depth of these source chambers may be approximately 50 mm and 200-300 mm, respectively.

Target Improvements

In sputtering chambers the film thickness uniformity of the deposited layer is determined by the chamber geometry (target and substrate size, as well as target to substrate spacing), the erosion pattern on the target surface, as well as process and material factors. Uniform target erosion is desirable since it provides high utilization of the target material and drastically reduces the chance of redeposition of sputtered target material that can eventually lead to defects in the deposited film. However, the film thickness uniformity of such an arrangement suffers unless the target is substantially larger than the substrate, which reduces overall material utilization.

Furthermore, it is desirable to have plasma energy uniformly deposited across the surface of the target to reduce thermal stresses within the target and reduce the chances of target cracking and particulate generation. This can be achieved as described below by shaping the target and also by spreading the plasma.

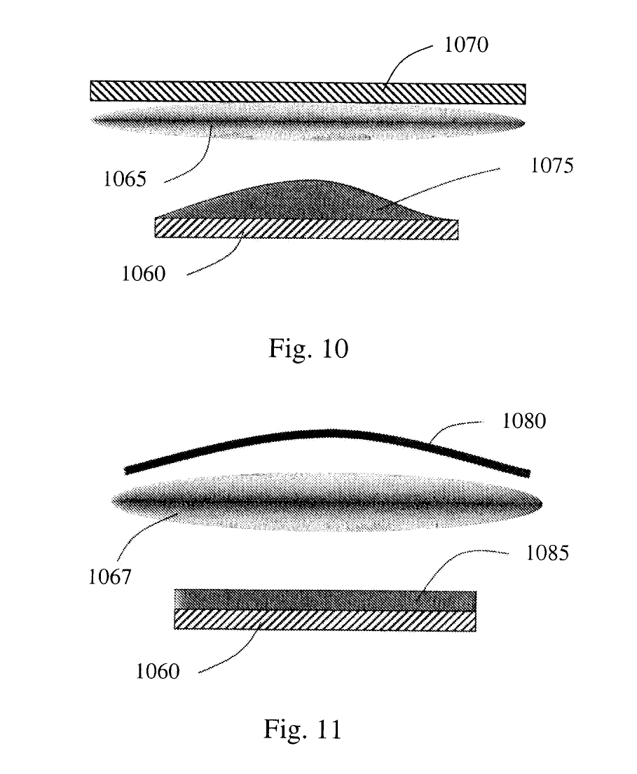

By shaping the target the film thickness uniformity can be optimized due to two factors: increasing target to substrate spacing reduces the deposition rate; and moving sections of the target surface away from the plasma region will lower the erosion rate. Non-planar target arrangements are very difficult to design and manufacture in case of a conventional sputtering source due to the resulting complex shape of the magnetron. Since there is no magnetron required when using a remote plasma source, the only hurdle is the manufacturability of the target, which may be forged, cast or tiled. FIGS. 10 and 11 provide an example of a shaped target improving film thickness uniformity. FIG. 10 shows a representation of a film 1075 with non-uniform thickness sputter deposited on a substrate 1060 from a target 1070 with a plasma 1065. FIG. 11 illustrates a film 1085 with an improved film thickness uniformity, when compared to the film 1075 of FIG. 10, sputter deposited on a substrate 1060 from a shaped target 1080 with a plasma 1067. The shaped target 1080 is shown with a concave surface.

Spreading of Plasma for Covering Full Target Area

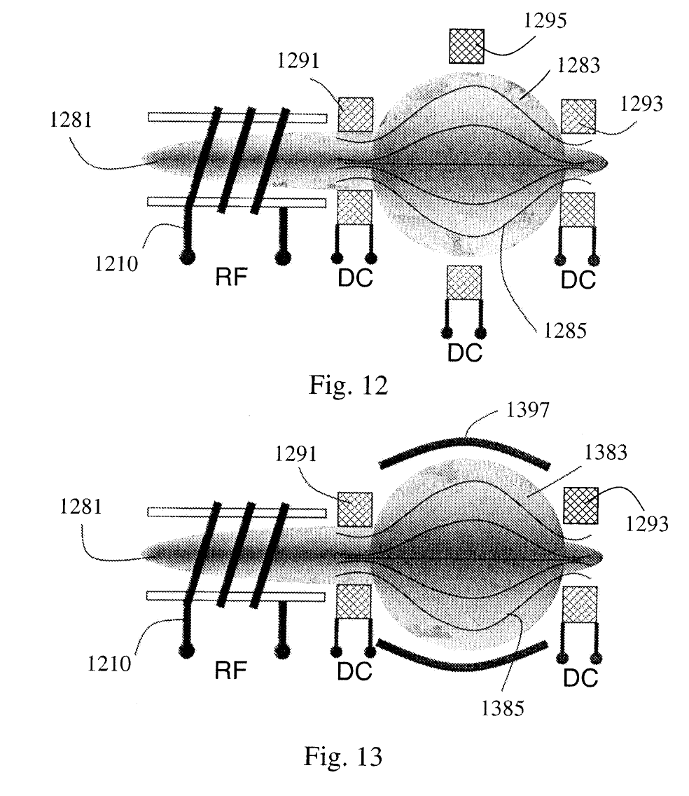

In the case of a circular substrate, such as a semiconductor wafer, the highest material utilization is provided by a circular sputtering target. However, a plasma beam generated by a remote plasma source will generally only cover a portion of the total area of the target. To cover the full target area the field generated by the electromagnets acting on the deposition chamber must be altered in a way that causes the plasma to spread out. This may be accomplished by using additional electromagnets or possibly by a permanent magnet or magnetic material, as shown in FIGS. 12 and 13, respectively.

FIG. 12 shows a plasma 1281 generated in a source chamber with RF coil 1210 being spread to form a plasma 1283 in the deposition chamber using an electromagnet 1295—in addition to the electromagnets 1291 and 1293. The magnetic field lines 1285 are shown in the deposition chamber.

FIG. 13 shows a plasma 1281 generated in a source chamber with RF coil 1210 being spread to form a plasma 1383 in the deposition chamber using a permanent magnet (or magnetic material) 1397—in addition to the electromagnets 1291 and 1293. The magnetic field lines 1385 are shown in the deposition chamber.

The plane of the page in FIGS. 12 & 13 cuts through the plasma in between the target and the substrate positioned on a substrate holder. The plane of the page is parallel to the surface of the substrate, and to the surface of the target for targets with planar surfaces. The field lines of the additional magnets should be parallel with the ones generated by electromagnets 1283 and 1291. Note that for magnet 1397, the piece of magnetic material (steel or a permanent magnet) could be used to distort the magnetic field generated by electromagnets 1291 and 1293. Furthermore, the different magnets and electromagnets may be placed outside the interior of the vacuum chamber, or may be appropriately encapsulated and placed within the vacuum chamber outside of the process kit.

Although the present invention has been described herein with respect to LiPON, the present invention is applicable to a wide range of dielectric targets, such as those used in the semiconductor industry. The improvements to the plasma source and improvements to the deposition chamber described herein permit the use of remote plasma sources for sputtering of large size dielectric targets typically used in semiconductor integrated circuit manufacturing—13 inch targets for 200 mm substrates and 17 inch targets for 300 mm substrates.

Although the present invention has been particularly described with reference to certain embodiments thereof, it should be readily apparent to those of ordinary skill in the art that changes and modifications in the form and details may be made without departing from the spirit and scope of the invention.

What is claimed is:

1. A sputter deposition system, comprising:
a vacuum chamber including a vacuum pump for maintaining a vacuum in said vacuum chamber;
a gas inlet for supplying process gases to said vacuum chamber;
a sputter target within said vacuum chamber;
a substrate holder; and
a plasma source attached to said vacuum chamber and positioned remotely from said sputter target, said plasma source being configured to form a high density plasma beam extending into said vacuum chamber, said plasma source comprising:
a rectangular cross-section source chamber;
an electromagnet; and
a radio frequency coil;
wherein said rectangular cross-section source chamber and said radio frequency coil are configured to give said high density plasma beam an elongated ovate cross-section.

2. The system of claim 1, wherein said radio frequency coil is helically wound around said rectangular cross-section source chamber.

3. The system of claim 1, wherein said radio frequency coil is foamed in a spiral on a longer side of said rectangular cross-section source chamber.

4. The system of claim 1, wherein the surface of said sputter target is configured in a non-planar form to provide uniform sputter deposition at the surface of a substrate on said substrate holder.

5. The system of claim 4, wherein the surface of said sputter target is concave.

6. The system of claim 1, wherein the surface of said sputter target is configured in a non-planar form to provide uniform plasma energy deposition into said sputter target.

7. The system of claim 1, wherein said sputter target comprises lithium orthophosphate.

8. The system of claim 1, wherein said sputter target is circular with an approximately thirteen inch diameter.

9. The system of claim 1, wherein said sputter target is circular with an approximately seventeen inch diameter.

10. A sputter deposition system, comprising:
a vacuum chamber including a vacuum pump for maintaining a vacuum in said vacuum chamber;
a gas inlet for supplying process gases to said vacuum chamber;
a sputter target within said vacuum chamber;
a substrate holder;
a plasma source attached to said vacuum chamber and positioned remotely from said sputter target, said plasma source being configured to form a high density plasma beam extending into said vacuum chamber; and
a plasma spreading system for reshaping said high density plasma beam for complete and uniform coverage of said sputter target.

11. The system of claim 10, wherein said substrate holder is configured for circular substrates and said sputter target is circular.

12. The system of claim 11, wherein said sputter target has an approximately thirteen inch diameter.

13. The system of claim 11, wherein said sputter target has an approximately seventeen inch diameter.

14. The system of claim 10, wherein said plasma spreading system comprises a first plurality of electromagnets.

15. The system of claim 10, wherein said plasma spreading system comprises a permanent magnet and a second plurality of electromagnets.

16. The system of claim 10, wherein said plasma source comprises a radio frequency antenna and an electromagnet.

17. The system of claim 10, wherein the surface of said sputter target is configured in a non-planar foiin to provide uniform sputter deposition at the surface of a substrate on said substrate holder.

18. The system of claim 17, wherein the surface of said sputter target is concave.

19. The system of claim 10, wherein the surface of said sputter target is configured in a non-planar form to provide uniform plasma energy deposition into said sputter target.

20. The system of claim 10, wherein said sputter target comprises lithium orthophosphate.
